(19) United States
(12) Patent Application Publication
(10) Pub. No.: US 2005/0053801 A1
(43) Pub. Date: Mar. 10, 2005

(54) Transparent electrode for electro-optical structures

(76) Inventors: Andreas Elschner, Mulheim (DE); Udo Merker, Koln (DE); Armin Sautter, Shanghai (CN)

Correspondence Address: BAYER MATERIAL SCIENCE LLC, 100 BAYER ROAD, PITTSBURGH, PA, 15205, US

(21) Appl. No.: 10/910,042

(22) Filed: Aug. 3, 2004

(30) Foreign Application Priority Data
Aug. 5, 2003 (DE) 10335727.0

(51) Int. Cl. B32B 9/00; B32B 19/00

(52) U.S. Cl. 428/690

(57) ABSTRACT

A transparent electrode that includes a first layer that is interposed between a substrate (e.g., of inorganic glass) and a second layer, is described. The first layer includes a conductive polymer (e.g., a polythiophene), and the second layer includes at least one polymeric anion and at least one of a polyanaline, a substituted polyaniline and a polythiophene represented by the following general formula (I), 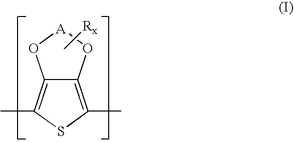
in which A may be a C₁-C₅ alkylene radical, R may be a linear or branched C₁-C₁₈ alkyl radical, and x is 0 to 8, provided that when x is greater than 1, each R may be the same or different. Also described is a method of preparing the transparent electrode, and articles of manufacture (e.g., an electroluminescent array) that include the transparent electrode of the present invention.

### CROSS REFERENCE TO RELATED PATENT APPLICATION

The present patent application claims the right of priority under 35 U.S.C. § 119 (a)-(d) of German Patent Application No. 103 35 727.0, filed Aug. 5, 2003.

### FIELD OF THE INVENTION

The invention relates to transparent electrodes comprising conductive polymers, to the production thereof and to the use thereof in electro-optical structures.

### BACKGROUND OF THE INVENTION

Displays based on organic light-emitting diodes (OLEDs) are an alternative to the established technology of liquid crystals (LCDs), owing to their particular properties. This new technology is advantageous, in particular, in applications involving portable equipment that is isolated from the landline network such as, for example, mobile telephones, pagers and toys.

Advantages of OLEDs include the extremely flat construction, the property of generating light themselves, i.e. of managing without an additional light source as in the case of liquid crystal displays (LCDs), the high luminous efficiency and freedom in the viewing angle.

In addition to displays, however, OLEDs can also be used for lighting purposes, for example in large-area emitters. Owing to their extremely flat construction, they may be used to construct very thin lighting elements, which was not possible in the past. The luminous efficiency of OLEDs has in the meantime exceeded that of thermal emitters such as incandescent bulbs, and the emission spectrum may, in principle, be varied as desired by appropriate choice of the emitter materials.

Neither OLED displays nor OLED lighting elements are restricted to a flat, rigid construction. Arrangements that are flexible or curved in any way may also be produced owing to the flexibility of the organic functional layers.

One advantage of organic light-emitting diodes lies in their simple structure. This structure is usually made up as follows: a transparent electrode is applied to a transparent carrier, for example glass or plastic film. This is followed by at least one organic layer (emitter layer) or a stack of organic layers applied in succession. A metal electrode is finally applied.

Organic solar cells (OCSs) have basically the same structure (Halls et al., Nature 1995, 376, 498), except that in contrary light is converted into electrical energy here.

The economic success of these new electro-optical structures will depend not only on fulfilment of the technical requirements but also substantially on production costs. Simplified processing steps, which reduce production costs, are therefore very important.

Layers of TCOs (transparent conducting oxides), such as indium-tin oxide (ITO) or antimony-tin oxide (ATO) or thin layers of metal were conventionally used in the past as transparent electrodes in OLEDs or OSCs. Deposition of these inorganic layers was by sputtering, reactive sputtering or thermal evaporation of the in organic material under vacuum and was therefore complex and expensive.

ITO layers are a significant cost factor in the production of OLEDs or OCSs. ITO layers are used on account of their high electrical conductivity and simultaneous high transparency. However, ITO has the following considerable drawbacks:
a) ITO can only be deposited by a complex, expensive vacuum process (reactive sputtering).
b) Temperatures of T>400° C. are required for achieving high conductivity during the deposition process. In particular, the polymer substrates, which are important for flexible displays, cannot withstand these temperatures.
c) ITO is brittle and develops cracks during shaping.
d) The metal indium is a raw material that is produced in limited quantities, and shortages are predicted as consumption increases.
e) The problem of environmentally acceptable disposal of electro-optical structures that contain the heavy metal indium has not yet been solved.

In spite of these drawbacks, ITO layers are still used on account of their favourable ratio of electrical conductivity to optical absorption and, in particular, the lack of suitable alternatives. High electrical conductivity is required to maintain the low drop in voltage over the transparent electrode of electric current-driven structures.

Alternatives to ITO for the electrode materials have been discussed in the past, but an alternative that does not have the above-described drawbacks and at the same time produces comparably good properties in electro-optical structures has not yet been found.

Thus, for example, a complex of polyethylenedioxythiophene and polystyrene sulphonic acid, also abbreviated by specialists to PEDT/PSS or PEDT:PSS, has been proposed as a substitute for ITO as an electrode material (EP-A 686 662, Inganäs et al. Adv. Mater. 2002, 14, 662-665; Lee et al. Thin Solid Films 2,000, 363, 225-228; Kim et al. Appl. Phys. Lett. 2002, Vol. 80, No. 20, 3844±3846). The surface resistance of PEDT:PSS layers depends on the mixing ratio of PEDT to PSS and on the addition of additives. Electrodes of a mere PEDT/PSS layer are unsuitable as a substitute for ITO electrodes on account of their excessively low conductivity. Although the conductivity can be increased by addition of additives such as N-methylpyrrolidone, sorbitol or glycerol, these layers are also unsuitable as electrode materials owing to the coarser particles and the associated higher likelihood of a short-circuit in OLEDs and OSCs.

Although the use of layers that are polymerised in situ, in particular of PEDT that is polymerised in situ, also shortened by specialists to in situ PEDT, as a substitute for ITO for transparent electrodes is also described (WO-A 96/08047), in situ PEDT has the significant drawback for applications in OLEDs that the luminous efficiencies achievable are very low.

Therefore, there was still a need for transparent electrodes which could be used as an equivalent substitute for ITO electrodes in electrical and electro-optical structures.

### SUMMARY OF THE INVENTION

It was accordingly the object of the invention to produce transparent electrodes which are able to replace conventional expensive ITO electrodes but do not have the aforementioned drawbacks.

It has surprisingly been found that an electrode containing a layer of a conductive polymer on the layer containing at least one polymeric anion and at least one polythiophene meets these requirements.

In accordance with the present invention, there is provided a transparent electrode, characterised in that it contains a first layer containing at least one conductive polymer, to which is applied a second layer containing at least one polymeric anion and at least one optionally substituted polyaniline and/or at least one polythiophene with recurring units of general formula (I), 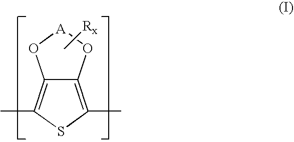
wherein
A represents an optionally substituted C₁ to C₅ alkylene radical, preferably an optionally substituted C₂ to C₃ alkylene radical
R represents a linear or branched, optionally substituted C₁ to C₁₈ alkyl radical, preferably a linear or branched, optionally substituted C₁ to C₁₄ alkyl radical, an optionally substituted C₅ to C₁₂ cycloalkyl radical, an optionally substituted C₆ to C₁₄ aryl radical, an optionally substituted C₇ to C₁₈ aralkyl radical, an optionally substituted C₁ to C₄ hydroxyalkyl radical, preferably optionally substituted C₁ to C₂ hydroxyalkyl radical, or a hydroxyl radical,
x represents an integer from 0 to 8, preferably from 0 to 6, particularly preferably 0 or 1 and,
   if a plurality of radicals R are bound to A, they may be same or different.

The features that characterize the present invention are pointed out with particularity in the claims, which are annexed to and form a part of this disclosure. These and other features of the invention, its operating advantages and the specific objects obtained by its use will be more fully understood from the following detailed description and accompanying drawings in which preferred embodiments of the invention are illustrated and described.

Unless otherwise indicated, all numbers or expressions used in the specification and claims are understood as modified in all instances by the term “about.”

### BRIEF DESCRIPTION OF THE DRAWINGS

FIG. 1 is a schematic representation of a passive matrix organic light-emitting diode (OLED) according to the present invention; and

FIG. 2 is a representative is a schematic representation of a homogeneously illuminated organic light-emitting diode (OLED) according to the present invention.

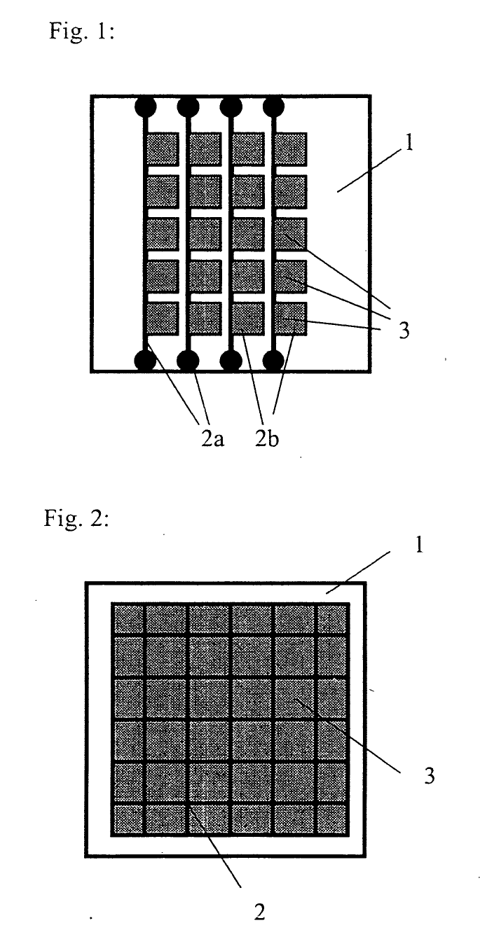

In FIGS. 1 and 2, like reference numerals designate the same components and structural features, unless otherwise indicated.

### DETAILED DESCRIPTION OF THE INVENTION

The first layer containing at least one conductive polymer will also be designated herein as electrical conductive layer.

General formula (I) is to be taken to mean that x substituents R may be bound to the alkylene radical.

Preferably, a layer containing at least one polymeric anion and at least one polythiophene with recurring units of general formula (I) is applied to at least one side, and more preferably to just one side of the first layer which contains at least one conductive polymer.

Preferred conductive polymers include optionally substituted polythiophenes, polypyrroles or polyanilines, and polythiophenes with recurring units of general formula (I) are particularly preferred.

In preferred embodiments, polythiophenes with recurring units of general formula (I) are those with recurring units of general formula (Ia), 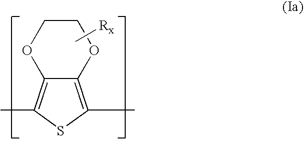
wherein
R and x have the meaning given above.

In further preferred embodiments, polythiophenes are those with recurring units of general formula (Iaa)

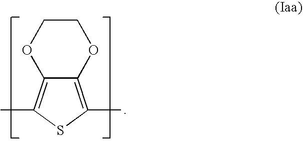

Within the context of the invention, the prefix poly is taken to mean that more than one identical or different recurring unit is contained in the polymer or polythiophene. The polythiophenes contain a total of n recurring units of general formula (I), n in particular being an integer from 2 to 2,000, preferably 2 to 100. The recurring units of general formula (I) may each be the same or different within a polythiophene. Polythiophenes with identical recurring units of general formula (I), (II) in each case are preferred.

At the terminal groups, the polythiophenes each preferably carry H.

In a particularly preferred embodiment, the polythiophene with recurring units of general formula (I) is poly (3,4-ethylenedioxythiophene), i.e. a homopolythiophene comprising recurring units of formula (Iaa).

C₁ to C₅ alkylene radicals A, within the scope of the invention, are methylene, ethylene, n-propylene, n-butylene or n-pentylene. Within the context of the invention, C₁ to C₁₈ alkyl represents linear or branched C₁ to C₁₈ alkyl radicals such as methyl, ethyl, n- or iso-propyl, n-, iso-, sec- or tert-butyl, n-pentyl, 1-methylbutyl, 2-methylbutyl, 3-methylbutyl, 1-ethylpropyl, 1,1-dimethylpropyl, 1,2-dimethylpropyl, 2,2-dimethylpropyl, n-hexyl, n-heptyl, n-octyl, 2-ethylhexyl, n-nonyl, n-decyl, n-undecyl, n-dodecyl, n-tridecyl, n-tetradecyl, n-hexadecyl or n-octadecyl, C₅ to C₁₂ cycloalkyl for C₅ to C₁₂ cycloalkyl radicals such as cyclopentyl, cyclohexyl, cycloheptyl, cyclooctyl, cyclononyl or cyclodecyl, C₅ to C₁₄ aryl for C₅ to C₁₄ aryl radicals such as phenyl or naphthyl, and C₇ to C₁₈ aralkyl for C₇ to C₁₈ aralkyl radicals, such as benzyl, o-, m-, p-tolyl, 2,3-, 2,4-, 2,5-, 2,6-, 3,4-, 3,5-xylyl or mesityl. The preceding list is used by way of example to illustrate the invention and should not be regarded as conclusive.

Numerous organic groups may be considered as optional further substituents for C₁ to C₅ alkylene radicals A, for example alkyl, cycloalkyl, aryl, halogen, ether, thioether, disulphide, sulphoxide, sulphone, sulphonate, amino, aldehyde, keto, carboxylic acid ester, carboxylic acid, carbonate, carboxylate, cyano, alkylsilane and alkoxysilane groups and carboxylamide groups.

Examples of preferred polymeric anions include anions of polymeric carboxylic acids such as polyacrylic acids, polymethacrylic acid or polymaleic acids, or polymeric sulphonic acids such as polystyrene sulphonic acids and polyvinyl sulphonic acids. These polycarboxylic and sulphonic acids may also be copolymers of vinyl carboxylic and vinyl sulphonic acids with other polymerisable monomers such as acrylic acid esters and styrene.

The anion of polystyrene sulphonic acid (PSS) as a counterion is particularly preferred as a polymeric anion.

The molecular weight of the polyacids delivering the polyanions is preferably 1,000 to 2,000,000, particularly preferably 2,000 to 500,000. The polyacids or the alkali metal salts thereof are commercially available, for example polystyrene sulphonic acids and polyacrylic acids, or alternatively may be produced by known processes (cf. for example Houben Weyl, Methoden der organischen Chemie, Vol. E 20 Makromolekulare Stoffe, Part 2, (1987), pp 1141).

The conductive polymers or polythiophenes may be neutral or cationic. In preferred embodiments they are cationic, “cationic” only referring to the charges located on the polymer-or polythiophene main chain. Depending on the substituent on the radicals R, the polymers or polythiophenes may carry positive and negative charges in the structural unit, the positive charges being located on the polymer or polythiophene main chain and the negative charges optionally on the radicals R substituted by sulphonate or carboxylate groups. In this case the positive charges of the polymer or polythiophene main chain may be partially or wholly compensated with the optionally present anionic groups on the radicals R. Viewed overall, the polymers or polythiophenes may, in these cases, be cationic, neutral or even anionic. Nevertheless, they are all regarded as cationic polymers or polythiophenes within the scope of the invention as the positive charges on the polythiophene main chain are crucial. The positive charges are not illustrated in the formulae as their exact number and position cannot be perfectly established. However, the number of positive charges is at least one and at most n, n being the total number of all recurring units (identical or different) within the polymer or polythiophene.

To compensate the positive charge, if this has not already occurred as a result of the optionally sulphonate- or carboxylate-substituted and therefore negatively charged radicals R, the cationic polymers or polythiophenes require anions as the counterions.

Counterions may be monomeric or polymeric anions, the latter also being called polyanions hereinafter.

Suitable polymeric anions include those listed hereinbefore. Suitable monomeric anions include, for example, those of C₁ to C₂₀ alkane sulphonic acids, such as methane, ethane, propane, butane or higher sulphonic acids, such as dodecane sulphonic acid, of aliphatic perfluorosulphonic acids, such as trifluoromethane sulphonic acid, perfluorobutane sulphonic acid or the perfluorooctane sulphonic acid, of aliphatic C₁ to C₂₀ carboxylic acids such as 2-ethyl-hexylcarboxylic acid, of aliphatic perfluorocarboxylic acids, such as trifluoroacetic acid or perfluorooctanoic acid, and of aromatic sulphonic acids optionally substituted by C₁ to C₂₀ alkyl groups, such as benzene sulphonic acid, o-toluene sulphonic acid, p-toluene sulphonic acid or dodecylbenzene sulphonic acid and of cycloalkane sulphonic acids such as camphor sulphonic acid or tetrafluoroborates, hexafluorophosphates, perchlorates, hexofluoroantimonates, hexafluoroarsenates or hexachloroantimonates.

The anions of p-toluene sulphonic acid, methane sulphonic acid or camphor sulphonic acid are particularly preferred.

Cationic polythiophenes that contain anions as counterions for charge compensation are often also known by experts as polythiophene/(poly)anion complexes.

The polymeric anion can act as a counterion in the layer containing at least one polymeric anion and at least one polythiophene with recurring units of general formula (I). However, additional counterions may also be contained in the layer. Preferably, however, the polymeric anion acts as a counterion in this layer.

Polymeric anion(s) and polythiophene(s) may be present in the layer in a ratio by weight of 0.5:1 to 50:1, preferably 1:1 to 30:1, particularly preferably 2:1 to 20:1. The weight of polythiophenes corresponds here to the weighed-in portion of the monomers used, assuming that there is a complete conversion during polymerisation.

In preferred embodiments, the transparent electrode contains a layer of a conductive polymer such as a polythiophene, polypyrrole or polyaniline, preferably a polythiophene with recurring units of general formula (I), wherein R, A and x have the meaning disclosed above to which a second layer of a polymeric anion and a polythiophene with recurring units of general formula (1) is applied.

In a particularly preferred embodiment, the transparent electrode according to the invention contains a layer of poly(3,4-ethylenedioxythiophene) to which is applied a layer containing polystyrene sulphonic acid and poly(3,4-ethylene-dioxythiophene), the latter also being known by specialists as PEDT/PSS or PEDT/PSS.

The transparent electrode according to the invention may be applied to a substrate. This substrate may be, for example, glass, ultrathin glass (flexible glass) or plastics materials.

Particularly suitable plastics materials for the substrate include: polycarbonates, polyesters such as PET and PEN (polyethylene terephthalate and polyethylene naphthalene dicarboxylate), copolycarbonates, polysulphone, polyethersulphone (PES), polyimide, polyethylene, polypropylene or cyclic polyolefins or cyclic olefin copolymers (COC), hydrogenated styrene polymers or hydrogenated styrene copolymers.

Suitable polymeric substrates include, for example, films such as polyester films, PES films produced by Sumitomo or polycarbonate films produced by Bayer AG (Makrofol®).

An adhesive layer may be placed between the substrate and the electrode. Silanes are examples of suitable adhesives. Epoxysilanes such as 3-glycidoxypropyl-trimethoxysilane (Silquest® A187, produced by OSi specialities) are preferred. Other adhesives having hydrophilic surface properties may also be used. Thus, for example, a thin layer of PEDT:PSS is described as an adhesive suitable for PEDT (Hohnholz et al., Chem. Commun. 2001, 2444-2445).

The electrode according to the invention has the advantage over the known transparent ITO-free electrodes described at the outset that it has both conductivity and good transmission.

The invention preferably relates to a transparent electrode with both polymer layers having surface resistance lower than or equal to 1,000 Ω/sq, more preferably lower than or equal to 500 Ω/sq, most preferably lower than or equal to 300 Ω/sq.

Transparent within the context of the present invention means transparent to visible light.

The invention also preferably relates to a transparent electrode having transmission of Y which is greater than or equal to 25, more preferably Y greater than or equal to 50.

The transmission will be measured according to the procedure described in ASTM D 1003-00. The transmission than will be calculated according to ASTM E 308 (sort of light C,2* observer).

The surface roughness of the electrode according to the invention is advantageously much lower than, for example, that of the electrodes known from EP-A 686 662, so the likelihood of a short-circuit in OLEDs and OSCs having the electrodes according to the invention is reduced.

For example, the surface roughness of the electrodes according to the invention may have a mean roughness value Ra lower than or equal to 3 nm, more preferably lower than or equal to 1.5 nm, most preferably lower than or equal to 1 nm.

The electrodes according to the invention may be applied very easily by consecutively applying all electrode layers from solution. This avoids complex, expensive vapour deposition or sputtering processes.

The electrodes are produced appropriately in that the layer containing at least one conductive polymer is produced from precursors for the production of conductive polymers, optionally in the form of solutions, directly in situ to a suitable substrate by polymerisation by chemical oxidation in the presence of one or more oxidising agents or by means of electropolymerisation, and the layer containing at least one polymeric anion and at least one polythiophene with recurring units of general formula (I) is applied to this layer from a dispersion containing at least one polymeric anion and at least one polythiophene with recurring units of general formula (I), optionally after drying and washing.

The present invention further relates to a process for producing an transparent, characterised in that a first layer containing at least one conductive polymer is produced by applying, to a substrate, precursors for producing conductive polymers optionally in the form of solutions and polymerising them by chemical oxidation in the presence of one or more oxidising agents or electrochemically to form the conductive polymers, and a second layer containing at least one polymeric anion and at least one optionally substituted polyaniline and/or at least one polythiophene with recurring units of general formula (I) 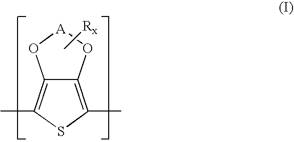
wherein
A, R and x have the meaning given above for formula (I), is applied to this conductive layer, optionally after washing and drying, by applying a dispersion containing at least one polymeric anion and at least one polythiophene with recurring units of general formula (I) and optionally containing a solvents and afterwards solidifying the dispersion optionally by removing the solvent or by crosslinking the dispersion.

The substrates already listed hereinbefore are suitable substrates. The substrate may be treated with an adhesive prior to application of the layer containing at least one conductive polymer. This treatment may be carried out, for example, by spin coating, impregnation, pouring, dropwise application, injection, spraying, doctoring, brushing or printing, for example inkjet, screen, contact or pad printing.

Precursors for producing conductive polymers, hereinafter also called precursors, are taken to mean corresponding monomers or derivatives thereof. Mixtures of different precursors may also be used. Suitable monomeric precursors include, for example, optionally substituted thiophenes, pyrroles or anilines, preferably optionally substituted thiophenes of general formula (II) 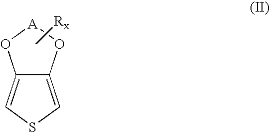
wherein
A, R and x have the meaning given above, more preferably optionally substituted 3,4-alkylenedioxythiophenes of general formula (IIa) 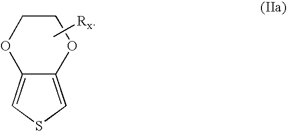
3,4-alkylenedioxythiophenes of formula (IIaa) 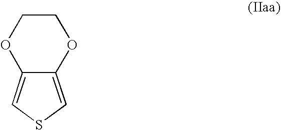
   are used as monomeric precursors in a preferred embodiment.

Derivatives of these monomeric precursors are understood, according to the invention, to include, for example, dimers or trimers of these monomeric precursors. Higher molecular derivatives, i.e. tetramers, pentamers, etc. of the monomeric precursors are also possible as derivatives. The derivatives may be made up of identical or different monomer units and used in pure form and in a mixture with one another and/or with the monomeric precursors. Oxidised or reduced forms of these precursors are also covered by the term “precursors” in the scope of the invention if, during the polymerisation thereof, the same conductive polymers are produced as in the precursors listed above.

The radicals mentioned for R for general formula (I) may be considered as substituents for the precursors, in particular for the thiophenes, preferably for the 3,4-alkylenedioxythiophenes.

Processes for producing the monomeric precursors for producing conductive polymers and their derivatives are known to the person skilled in the art and described, for example, in L. Groenendaal, F. Jonas, D. Freitag, H. Pielartzik & J. R. Reynolds. Adv. Mater. 12 (2000) 481-494 and the literature cited therein. The precursors may optionally be used in the form of solutions. The following organic solvents that are inert under the reaction conditions are primarily mentioned as solvents for the precursors: aliphatic alcohols such as methanol, ethanol, i-propanol and butanol; aliphatic ketones such as acetone and methylethylketone; aliphatic carboxylic acid esters such as ethyl acetate and butyl acetate; aromatic hydrocarbons such as toluene and xylene; aliphatic hydrocarbons such as hexane, heptane and cyclohexane; chlorohydrocarbons such as dichloromethane and dichloroethane; aliphatic nitriles such as acetonitrile, aliphatic sulphoxides and sulphones such as dimethyl sulphoxide and sulpholane; aliphatic carboxylic acid amides such as methylacetamide, dimethylacetamide and dimethylformamide; aliphatic and araliphatic ethers such as diethylether and anisole. Water or a mixture of water with the above-mentioned organic solvents may also be used as the solvent.

Further components such as one or more organic binders that are soluble in organic solvents, such as polyvinyl acetate, polycarbonate, polyvinyl butyral, polyacrylic acid ester, polymethacrylic acid ester, polystyrene, polyacrylonitrile, polyvinylchloride, polybutadiene, polyisoprene, polyether, polyester, silicones, styrene/acrylic acid ester, vinyl acetate/acrylic acid ester and ethylene/vinyl acetate copolymers or water-soluble binders such as polyvinyl alcohols, crosslinking agents such as polyurethanes or polyurethane dispersions, polyacrylates, polyolefin dispersions, epoxy silanes such as 3-glycidoxypropyltrialkoxysilane, and/or additives, such as imidazole or surface-active substances may also be added to the solutions. Alkoxysilane hydrolysates based, for example, on tetraethoxysilane may also be added to increase the scratch resistance of the coatings.

The presence of one or more oxidising agents is required if the precursors are polymerised to the conductive polymers by chemical oxidation.

Any metal salts suitable for oxidative polymerisation of thiophenes, anilines or pyrroles and known to the person skilled in the art may be used as the oxidising agents.

Suitable metal salts include metal salts of main and subgroup metals, the subgroup metals also being called transition metal salts hereinafter, of the periodic table of elements. Suitable transition metal salts include, in particular, salts of an inorganic or organic acid or inorganic acid of transition metals, such as iron(III), copper (II), chromium (VI), cerium (IV), manganese (IV), manganese (VII) and ruthenium (III), comprising organic radicals.

Preferred transition metal salts include those of iron(III). Iron(III) salts are frequently inexpensive, easily obtainable and may be easily handled, such as the iron(III) salts of inorganic acids, for example iron(III) halides (e.g. FeCl₃) or iron(III) salts of other inorganic acids, such as Fe(ClO₄) or Fe₂(SO₄)₃ and the iron(III) salts of organic acids and inorganic acids comprising organic radicals. The iron(III) salts of sulphuric acid monoesters of C₁ to C₂₀ alkanols, for example the iron(III) salt of lauryl sulphate, are mentioned as examples of the iron(III) salts of inorganic acids comprising organic radicals.

Particularly preferred transition metal salts include those of an organic acid, in particular iron(III) salts of organic acids.

Examples of iron(III) salts of organic acids include: iron(III) salts of C₁ to C₂₀ alkane sulphonic acids, such as methane, ethane, propane, butane or higher sulphonic acids such as dodecane sulphonic acid, of aliphatic perfluorosulphonic acids, such as trifluoromethane sulphonic acid, perfluorobutane sulphonic acid or perfluorooctane sulphonic acid, of aliphatic C₁ to C₂₀ carboxylic acids such as 2-ethylhexylcarboxylic acid, of aliphatic perfluorocarboxylic acids, such as trifluoroacetic acid or perfluorooctane acid and of aromatic sulphonic acids optionally substituted by C₁ to C₂₀ alkyl groups, such as benzene sulphonic acid, o-toluene sulphonic acid, p-toluene sulphonic acid or dodecylbenzene sulphonic acid and of cycloalkane sulphonic acids such as camphor sulphonic acid.

Any mixtures of these above-mentioned iron(III) salts of organic acids may also be used.

The use of the iron(III) salts of organic acids and of the inorganic acids comprising organic radicals has the great advantage that they are not corrosive.

Iron(III)-p-toluene sulphonate, iron(III)-o-toluene sulphonate or a mixture of iron(III)-p-toluene sulphonate and iron(III)-o-toluene sulphonate are more particularly preferred as the metal salts.

In preferred embodiments, the metal salts have been treated with an ion exchanger, preferably a basic anion exchanger, prior to their use. Examples of suitable ion exchangers include macroporous polymers made of styrene and divinylbenzene functionalised using tertiary amines, as sold, for example, under the trade name Lewatit® by Bayer AG, Leverkusen.

Peroxo compounds such as peroxodisulphates (persulphates), in particular ammonium and alkali peroxodisulphates, such as sodium and potassium peroxodisulphate, or alkali perborates—optionally in the presence of catalytic quantities of metal ions, such as iron, cobalt, nickel, molybdenum or vanadium ions—and transition metal oxides, such as manganese dioxide (manganese(IV) oxide) or cerium(IV) oxide are also suitable oxidising agents.

Theoretically, 2.25 equivalents of oxidising agents are required per mol for the oxidative polymerisation of the thiophenes of formula (II) (see for example J. Polym. Sc. Part A Polymer Chemistry vol. 26, p. 1287 (1988)). However, lower or higher equivalents of oxidising agents may also be used. According to the invention, one equivalent or more, particularly preferably two equivalents or more of oxidising agents is/are used per mol of thiophene.

The anions of the oxidising agent used can preferably serve as counterions, so it is not imperative to add additional counterions in the case of polymerisation by chemical oxidation.

The oxidising agents may be applied to the substrate together with or separately from the precursors—optionally in the form of solutions. If precursors, oxidising agents and optionally counterions are applied separately, the substrate is preferably initially coated with the solution of the oxidising agent and optionally the counterions and then with the solution of the precursors. With the preferred combined application of thiophenes, oxidising agents and optionally counterions, the oxide layer of the anode body is coated only with one solution, namely a solution containing thiophenes, oxidising agents and optionally counterions. The solvents described hereinbefore as being suitable for the precursors are suitable in all cases.

As further components, the solutions may also contain the components (binders, crosslinking agents etc.) already described hereinbefore for the solutions of the precursors.

The solutions to be applied to the substrate preferably contain 1 to 30% by weight of the thiophenes of general formula (I) and optionally 0 to 50% by weight binder, crosslinking agent and/or additives, both percentages by weight being based on the total weight of the mixture.

The solutions are applied to the substrate by known methods, for example by spin coating, impregnation, pouring, dropwise application, injection, spraying, doctoring, brushing or printing, for example ink-jet, screen or pad printing.

The solvent optionally present may be removed after application of the solutions by simple evaporation at ambient temperature. To achieve higher processing speeds it is, however, more advantageous to remove the solvent at elevated temperatures, for example at temperatures of 20 to 300° C., preferably 40 to 250° C. A thermal post-treatment may be directly connected with removal of the solvent or else also be performed following a delay after completion of the coating. The solvent may be removed before, during or after polymerisation.

The duration of the heat treatment may be from 5 seconds to a plurality of seconds, depending on the type of polymer used for the coating. Temperature profiles with different temperatures and dwell times may also be used for the thermal treatment.

The heat treatment may, for example, be carried out in such a way that the coated substrates are moved at such speed through a heat chamber at the desired temperature that the desired dwell time is achieved at the selected temperature or it is brought into contact with a hot plate at the desired temperature for the desired dwell time. The heat treatment may also take place, for example, in a heating oven or a plurality of heating ovens with respectively different temperatures.

After removing the solvent (drying) and optionally after thermal post-treatment, it may be advantageous to wash excess oxidising agents and residual salts from the coating using a suitable solvent, preferably water or alcohols. Residual salts are here taken to mean the salts of the reduced form of the oxidising agents and optionally further salts present.

The alternative electrochemical polymerisation may be carried out by processes known to the person skilled in the art.

If the monomers in particular the thiophenes of general formula (II) are liquid, electropolymerisation may be performed in the presence or absence of solvents that are inert under electropolymerisation conditions. The electropolymerisation of solid monomers in particular thiophenes of general formula (II) is carried out in the presence of solvents that are inert under electrochemical polymerisation conditions. In certain cases it may be advantageous to use solvent mixtures and/or to add solubilisers (detergents) to the solvents.

Examples of solvents that are inert under electropolymerisation conditions include: water; alcohols such as methanol and ethanol; ketones such as acetophenone; halogenated hydrocarbons such as methylene chloride, chloroform, carbon tetrachloride and fluorocarbons; esters such as ethyl acetate and butyl acetate; carbonic acid esters such as propylene carbonate; aromatic hydrocarbons such as benzene, toluene, xylene; aliphatic hydrocarbons such as pentane, hexane, heptane and cyclohexane; nitriles such as acetonitrile and benzonitrile; sulphoxides such dimethylsulphoxide; sulphones such as dimethylsulphone, phenylmethylsulphone and sulpholane; liquid aliphatic amides such as methylacetamide, dimethylacetamide, dimethylformamide, pyrrolidone, N-methy-pyrrolidone, N-methylcaprolactam; aliphatic and mixed aliphatic-aromatic ethers such as diethylether and anisole; liquid ureas such as tetramethylurea or N,N-dimethylimidazoldinone.

For electropolymerisation, electrolyte additives are added to the thiophenes of general formula (II) or their solutions. Free acids or conventional conductive salts, that have some solubility in the solvents used, are preferably used as the electrolyte additives. Free acids, such as p-toluene sulphonic acid, methane sulphonic acid, and salts with alkane sulphonate, aromatic sulphonate, tetrafluoroborate, hexafluorophosphate, perchlorate, hexafluoroantimonate, hexafluoroarsenate and hexachloroantimonate anions and alkali, alkaline earth or optionally alkylated ammonium, phosphonium, sulphonium and oxonium cations, for example, have proven themselves as electrolyte additives.

The concentration of the monomers in particular of the thiophenes of general formula (II) can lie between 0.01 and 100% by weight (100% by weight only with liquid thiophene); the concentration is preferably 0.1 to 20% by weight, based on the total weight of the solution.

Electropolymerisation may be carried out discontinuously or continuously.

The current density for electropolymerisation may vary within wide limits; a current density of 0.0001 to 100 mA/cm², preferably 0.01 to 40 mA/cm², is conventionally employed. A voltage of about 0.1 to 50 V is obtained with these current densities.

Suitable counterions include those already listed hereinbefore. During electrochemical polymerisation, these counterions may be added to the solution or the thiophenes, optionally as electrolyte additives or conductive salts.

Polymerisation of the thiophenes of general formula (I) by electrochemical oxidation may be carried out at a temperature from −78° C. to the boiling point of the solvent optionally used. Electrochemical polymerisation is preferably carried out at a temperature from −78° C. to 250° C., more preferably from −20° C. to 60° C.

The reaction times preferably range from 1 minute to 24 hours, depending on the thiophene used, the electrolyte used, the temperature selected and the current density applied.

During electrochemical polymerisation, the substrate, which is not generally conductive, may initially be coated with a thin transparent layer of a conductive polymer, as described in Groenendaal et al. Adv. Mat. 2003, 15, 855. The substrate, which is provided with a conductive coating in this way and has surface resistance of ≧10⁴ Ω/sq, assumes the role of the Pt electrode during subsequent electropolymerisation. The layer containing the conductive polymer grows thereon when a voltage is applied.

As the conductive polymer(s) in the layer containing at least one conductive polymer is (are) applied directly to the substrate in situ by polymerisation of precursors, this layer will hereinafter also be called “in situ layer”. The concept of in situ deposition of a conductive polymer from a polymerisable solution of monomer and oxidising agent is generally known to specialists.

A layer containing at least one polymeric anion and at least one optionally substituted polyaniline and/or at least one polythiophene with recurring units of general formula (I) is then applied to the in situ layer from a dispersion containing at least one polymeric anion and at least one optionally substituted polyaniline and/or at least one polythiophene with recurring units of general formula (I).

A layer containing at least one polymeric anion and at least one polythiophene with recurring units of general formula (I) is preferably applied to the in situ layer from a dispersion containing at least one polymeric anion and at least one polythiophene with recurring units of general formula (I).

The dispersions may also contain one or more solvents. The solvents already mentioned above for the precursors may be used as the solvents. Preferred solvents are water or other protic solvents such as alcohols, for example methanol, ethanol, i-propanol and butanol and mixtures of water with these alcohols, the particularly preferred solvent being water.

The dispersion preferably can be solidified forming the second layer by evaporating the solvent in case of solvent containing dispersions or by oxidative crosslinking using oxygen.

The polymeric anions already listed above are suitable. Preferred ranges similarly apply.

That already stated in conjunction with the transparent electrode may be considered for the polythiophenes with recurring units of general formula (I). Preferred ranges analogously apply in any combination.

The dispersions are produced from thiophenes of general formula (II), for example analogously to the conditions mentioned in EP-A 440 957. The oxidising agents, solvents and polymeric anions already listed above may be used as the oxidising agents, solvents and polymeric anions.

Production of the polythiophene/polyanion complex and subsequent dispersal or redispersal in one or more solvent(s) is also possible.

The dispersions are applied by known processes, for example by spin coating, impregnation, pouring, dropwise application, injection, spraying, doctoring, brushing or printing, for example inkjet, screen or pad printing, onto the in situ layer.

Application of the layer containing at least one polymeric anion and at least one polythiophene with recurring units of general formula (I) may also be followed by drying and/or cleaning of the layer by washing—as already described hereinbefore—for the in situ layer.

A transparent electrode may be produced by the process according to the invention without the need for complex, expensive vapour deposition or sputtering processes. This also allows inter alia extensive application of the process according to the invention. The in situ layer as well as the polythiophene/polyanion layer may also be applied at low temperatures, preferably ambient temperature. The process according to the invention is therefore also suitable for application to polymeric flexible substrates that generally only tolerate low-temperature processes and do not withstand the temperatures during ITO deposition.

The electrodes according to the invention are eminently suitable as electrodes in electrical—and preferably in electro-optical—structures, in particular in organic light-emitting diodes (OLEDs), organic solar cells (OSC), liquid crystal displays (LCD) and optical sensors.

Electro-optical structures generally contain two electrodes, of which at least one is transparent, with an electro-optically active layer system in-between. In the case of OLEDs, the electro-optical structure is an electroluminescent layer arrangement, which will also be shortened to electroluminescent arrangement or EL arrangement hereinafter.

The simplest case of such an EL arrangement consists of two electrodes, of which at least one is transparent, and of an electro-optically active layer between these two electrodes. However, further functional layers may additionally be contained in such an electroluminescent layer structure, for example charge-injecting, charge-transporting or charge-blocking intermediate layers. Layer structures of this type are familiar to the person skilled in the art and described, for example, in J. R. Sheats et al. Science 273, (1996), 884. A layer may also assume a plurality of functions. In the simplest case of an EL arrangement, the layer, which is electro-optically active i.e. which generally emits light, can assume the functions of the other layers. Either electrode or both electrodes may be applied to a suitable substrate, i.e. a suitable carrier. The layer structure is then provided with appropriate contacts and optionally sheathed and/or encapsulated.

The structure of multilayer systems may be applied by chemical vapour deposition (CVD), during which the layers are applied in succession from the gaseous phase or by casting processes. Chemical vapour deposition is carried out in conjunction with the shadow mask technique for fabricating structured LEDs that employ organic molecules as emitters. Casting processes are generally preferred on account of the higher processing rates and the smaller amount of waste material produced and associated saving in costs.

As already described at the outset, the electrodes according to the invention may advantageously be produced from solution/dispersion.

The present invention accordingly also relates to an electroluminescent arrangement at least comprising two electrodes, of which electrodes at least one is a transparent electrode, and an electro-optical active layer between said electrodes containing an electrode according to the invention as transparent electrode.

Preferred electroluminescent arrangements according to the invention are those which contain an electrode according to the invention applied to a suitable substrate, i.e. contain an in situ layer and a layer containing at least one polymeric anion and at least one polythiophene of general formula (I), an emitter layer and a metal cathode. For example, the layer containing at least one polymeric anion and at least one polythiophene of general formula (I) can act as a hole-injecting intermediate layer in such an EL arrangement. More of the functional layers mentioned hereinbefore may optionally be contained.

The electrical conductive layer in a preferred embodiment is in contact with various highly conductive metallic lines as anode.

An EL arrangement comprising layers in the following sequence is a preferred embodiment:
Substrate//in situ PEDT (polyethylenedioxythiophene) layer//PEDT:PSS (polyethylenedioxythiophene/polystyrene sulphonic acid)//emitter layer//metal cathode.

Further functional layers may optionally be contained.

Appropriate structures with an electrode according to the invention are also advantageous in inverted OLED or OSC structures, i.e. if the layer structure is in the reverse sequence. A corresponding preferred embodiment of an inverted OLED is as follows:
Substrate//metal cathode//emitter layer//PEDT:PSS//in situ PEDT.

Inverted OLEDs, in particular in combination with active matrix substrates, are of great interest. Active matrix substrates are generally non-transparent layers of Si in which a transistor has been processed beneath each pixel of light.

Suitable emitter materials and materials for metal cathodes are those commonly used for electro-optical structures and familiar to a person skilled in the art. Metal cathodes made of metals with a minimal work function, such as Mg, Ca, Ba or metal salts such as LiF are preferred. Conjugated polymers such as polyphenylene vinylene or polyfluorenes or emitters from the category of low-molecular weight emitters, also known by specialists as small molecules, such as tris(8-hydroxy-quinolinato)aluminium (Alq₃) are preferred as emitter materials.

The electrode according to the invention has a number of advantages over known electrodes in electro-optical structures:
a) TCO layers, for example ITO, or thin metal layers may be dispensed with, for example, in OLEDs and OSCs.
b) In the case of flexible substrates, cracks do not occur in the brittle TCO layers and the electro-optical structure does not fail when the substrate is bent, as these polymeric layers are very ductile and flexible.
c) The somewhat higher absorption of the in situ layer in the case of thicker layers has the advantage that the contrast ratio between illuminated and dark regions is significantly improved in daylight. It is therefore unnecessary to apply a polarising film, which would also absorb 50% of the emitted light.
d) Organic layers may be structured more easily than inorganic layers such as ITO. Organic layers may be removed again by solvents, by optical irradiation (UV) or thermal irradiation (laser ablation).

A transparent electrode consisting solely of an in situ layer has a significant drawback for application in OLEDs, as the luminous efficiencies attainable are very low. Surprisingly, the application of a further conductive layer containing polymeric anions and polythiophenes with recurring units of general formula (I) leads to much higher luminous efficiencies. This layer may be very thin and have high specific resistance, as the device current required for light emission flows through the in situ layer underneath. The layers of poly(ethylene-oxythiophene)/poly(styrene sulphonic acid) (PEDT:PSS) already described hereinbefore have proven particularly suitable.

The effect found is unexpected, as the only electrically active component in both layers is the electrically conductive polymer or preferably polythiophene, whereas the polymeric anions are electrically inert and serve, in particular, to keep the electrically conductive polymer or polythiophene in solution during polymerisation.

In contrast to the above-described double layer according to the invention, electrodes consisting of only a polythiophene/polyanion layer, in particular of a PEDT:PSS layer, are also unsuitable for applications in OLEDs or OSCs on account of the excessively low conductivity or the excessively coarse particle structure. PEDT:PSS formulations which are suitable for such applications have a PEDT:PSS composition of 1:6 or 1:20, for example, and are distinguished by a very fine particle structure. However, the surface resistance of a 100 nm thick layer of these formulations is 50 MΩ/sq or 10 GΩ/sq. Therefore, these layers alone are unsuitable as a substitute for ITO electrodes with 10-50 Ω/sq owing to the excessively high surface resistance. Although, the electrical conductivity of a PEDT:PSS formulation with a higher PEDT content, for example with PEDT:PSS of 1:2.5, may be increased by addition of additives such as N-methylpyrrolidone, sorbitol or glycerol so surface resistances of about 10 kΩ/sq are achieved with a layer thickness of 100 nm, the surface resistances lower than 1000 Ω/sq with a layer thickness of 100 nm attainable in the double layer according to the invention cannot be achieved even with these PEDT:PSS formulations of higher conductivity. A further drawback of the formulations with a higher PEDT content is the coarse particle structure and the associated higher likelihood of a short-circuit in OLEDs and OSCs.

A special electrode according to the invention with a 100 nm thick in situ PEDT layer and a superimposed PEDT:PSS layer (PEDT:PSS ratio as in the preceding paragraph), on the other hand, has surface resistance lower than 1000 Ω/sq. Furthermore, the additional PEDT:PSS layer smoothes the in situ PEDT layer underneath. This is an additional advantage as it reduces the likelihood of short-circuits and increases the yield of functional OLEDs.

Moreover, the additional polythiophene/polyanion layer on the in situ layer in the electrode according to the invention significantly improves the efficiency of the electro-optical structure.

As described above highly conductive feed lines made, for example, of metal and known as ‘bus bars’ may be used to keep the voltage drop between anode contact point and OLED anode particularly low.

In the case of passive matrix OLED displays, ITO address lines may be dispensed with on account of the invention. In their place, metal supply lines (bus bars) combined with an electrode according to the invention carry out anode-side addressing (cf. FIG. 1). Electrical supply lines 2a and pixel frames 2b of high conductivity are applied to a transparent carrier 1, for example a pane of glass. They may be applied, for example, by vapour deposition of metals or inexpensively by printing with metal pastes. The polymeric electrode layer 3 is then deposited into the frames. An adhesive is optionally applied as the first layer, the in situ layer as the second layer and the layer containing the polythiophene(s) and polymeric anion(s) as the third layer. These layers are preferably applied by spin coating, printing and ink jetting. The remainder of the structure corresponds to that of a standard passive matrix OLED and is familiar to a person skilled in the art.

In the case of homogenously illuminated OLEDs (OLED lamps), ITO electrodes may be dispensed with on account of the invention. In their place, metal supply lines (bus bars) combined with an electrode according to the invention assume the function of the anode that covers the entire area (cf FIG. 2). Electric supply lines 2 of high conductivity are applied, for example as described in the preceding paragraph, to a transparent carrier 1, for example a pane of glass. The polymeric electrode layer 3 is then deposited thereon in the sequence described in the preceding paragraph. The remainder of the structure corresponds to that of a standard OLED lamp.

### EXAMPLES

### Example 1

1. Structured Substrates

ITO-coated glass substrates (Merck Display) are cut to a size of 50×50 mm² and cleaned. The ITO coating is then coated with photopositive resist (available from JSR, LCPR 1400G-80cP) and this is exposed through a printed polymer film (shadow mask) after drying. The shadow mask comprises isolated transparent circles that are 5 mm in diameter and are arranged in a square at intervals of 10 mm. After exposure and drying, the uncrosslinked photoresist is removed from the circle regions with the developer solution (available from JSR, TMA238WA). At these points, which are now unmasked, the ITO is subsequently removed with an etching solution consisting of 47.5% by volume distilled water, 47.5% by volume hydrochloric acid (32%), 5.0% by volume nitric acid (65%), the crosslinked photo resist is then removed with acetone and the structured ITO substrate is finally cleaned.

2. Production of the In Situ PEDT Layers:

Epoxysilane (Silquest® A187, OSi specialities) is diluted with 20 parts of 2-propanol, spun onto the cleaned, structured ITO substrate using a spin coater and then air-dried at 50° C. for 5 min. The layer is less than 20 nm thick. A solution comprising Baytron® M, Baytron® CB 40 and imidazole in a ratio by weight of 1:20:0.5 is prepared and filtered (Millipore HV, 0.45 μm). The solution is subsequently spun onto the epoxysilane-coated structured ITO substrate at 1000 rpm using a spin coater. The layer is then dried at ambient temperature (RT, 23° C.) and subsequently rinsed carefully with distilled water to remove the iron salts. After the layers have been dried in a rotary drier, the layer is approx. 150 nm thick. The surface roughness Ra is approx. 5 nm. The conductivity is 500 S/cm.

3. Application of the PEDT:PSS Layer:

Approx. 10 ml of the 1.3% polyethylenedioxythiophene/polystyrene sulphonic acid aqneous solution (Bayer AG, Baytron® P, TP AI 4083) are filtered (Millipore HV, 0.45 μm). The substrate is then placed on a paint spinner, and the filtered solution is distributed over the ITO-coated side of the substrate. The supernatant solution is then spun off by rotating the plate at 500 rpm for a period of 3 min. The substrate coated in this way is then dried on a heating plate for 5 min at 110° C. The layer is 60 nm thick (Tencor, Alphastep 500). The surface roughness Ra decreases to 1 nm.

The substrat with both layers according to point 2. and 3. has a transmission Y=55 (ASTM D1003-00; ASTM E 308).

4. Application of the Emitter Layer:

5 mL of a 1% by weight toluene solution of poly(2-methoxy-5-(2′-ethylhexyloxy)-1,4-phenylenevinylene) (MEH-PPV, Aldrich, red emitter) are filtered (Millipore HV, 0.45 μm) and distributed on the dried PEDT:PSS layer. The supernatant solution is then spun off by rotating the plate at 300 rpm for 30 seconds. The substrate coated in this way is subsequently dried on a heating plate for five min. at 110° C. The total layer thickness is 150 nm.

5. Application of the Metal Cathodes:

Metal electrodes are deposited on the organic layer system by vapour deposition. The vapour deposition apparatus (Edwards) used for this purpose is integrated in an inert gas glovebox (Braun). The substrate is lowered with the organic layer onto a shadow mask. The holes in the mask have a diameter of 2.5 mm and are arranged in such a way that they a) lie centrally over the circular regions of ITO removed by etching or b) over the regions of ITO not removed by etching. A 30 nm thick layer of Ca and then a 200 nm layer of Ag are deposited in succession by vapour deposition from two vapour deposition boats at a pressure of p=10-3 pA. The vapour deposition rates are 10 Å/second for Ca and 20 Å/second for Ag.

6. Characterisation of the OLEDs:

Two different OLEDs structures having the following vertical layer sequence are produced on the basis of the structured ITO substrates (step 1) and the positioning of the vapour deposition mask (step 5) on a substrate:
a) ITO//in situ PEDT//PEDT:PSS//emitter layer//Ca//Ag
b) in situ PEDT//PEDT:PSS//emitter layer//Ca//Ag

For electro-optical characterisation, the two electrodes of the OLED are connected to a voltage source via electric feed lines. The positive pole is connected to the ITO layer covering the entire layer and the negative pole is connected to one of the metal electrodes applied by vapour deposition. In the case of the OLED structures on ITO removed by etching (cf. b), the ITO not removed by etching serves only as a low-resistance electric feed line for the in situ PEDT layer.

The dependency of the OLED current and the intensity of electroluminescence (EL) on the voltage are recorded. The EL is detected by a photodiode (EG&G C30809E) and the luminance is calibrated by a luminance meter (Minolta LS-100).

### Example 2

Method as in Example 1 but Omitting Step 3 (Application of the PEDT:PSS Layer).

Summary of Results of Examples 1 and 2:

| | Current | | | |
|---|---|---|---|---|
| | density | Voltage | Luminance | Efficiency |
| OLED structure | [mA/cm²] | [V] | [cd/m²] | [cd/A] |
| ITO // in situ PEDT // | 102 | 5.1 | 105 | 0.10 |
| PEDT:PSS // MEH- | | | | |
| PPV // Ca // Ag | | | | |
| (cf. Example 1) | | | | |
| in situ PEDT // | 102 | 6.0 | 102 | 0.10 |
| PEDT:PSS // MEH- | | | | |
| PPV // Ca // Ag | | | | |
| (cf. Example 1) | | | | |
| ITO // in situ PEDT // | 102 | 6.6 | 19 | 0.019 |
| MEH-PPV // Ca //Ag | | | | |
| (cf. Example 2) | | | | |
| in situ PEDT // MEH- | 102 | 6.3 | 16 | 0.016 |
| PPV // Ca // Ag | | | | |
| (cf. Example 2) | | | | |

This shows that the luminance and efficiency of OLEDs with a luminescent area of at least 0.049 cm² are not dependent on whether or not the ITO is located below the in situ PEDT layer. Comparison of Examples 1 and 2 also shows that a PEDT:PSS layer between the in situ layer and the MEH-PPV layer (emitter layer) significantly improves the luminance.

### Example 3

Method as in Example 1 with the Following Difference in Step 4 (Application of the Emitter Layer):

5 mL of a 0.25% by weight chloroform solution of PF-F8 (Poly(9,9-dioctyl-fluorene)), a blue emitter synthesised by Yamamoto's method of polymerisation, which is described in detail in the literature, for example, T. Yamamoto et al., J. Am. Chem. Soc. 1996, 118, 10389-10399, and T. Yamamoto et al., Macromolecules 1992, 25, 1214-1223) are filtered (Millipore HV, 0.45 μm) and distributed on the dried PEDT:PSS layer. The supernatant solution is then spun off by rotating the plate for 30 seconds at 200 rpm. The substrate coated in this way is then dried on a heating plate for 5 min at 110° C. The total layer thickness is 130 nm.

### Example 4

Method as in Example 3, Except that Step 3 (Application of the PEDT:PSS Layer) is Omitted.

Summary of the Results of Examples 3 and 4:

| | Current | | | |
|---|---|---|---|---|
| | density | Voltage | Luminance | Efficiency |
| OLED structure | [mA/cm²] | [V] | [cd/m²] | [cd/A] |
| ITO // in situ PEDT // | 204 | 6.9 | 28 | 0.014 |
| PEDT:PSS // PF-F8 // | | | | |
| Ca//Ag | | | | |
| (cf. Example 3) | | | | |
| in situ PEDT // | 204 | 7.4 | 23 | 0.010 |
| PEDT:PSS // PF-F8 // | | | | |
| Ca // Ag | | | | |
| (cf. Example 3) | | | | |
| ITO // in situ PEDT // | 204 | 9.5 | 2.5 | 0.0012 |
| PF-F8 // Ca //Ag | | | | |
| (cf. Example 4) | | | | |
| in situ PEDT // PF-F8 // | 204 | 9.3 | 2.3 | 0.0011 |
| Ca // Ag | | | | |
| (cf. Example 4) | | | | |

This shows that the luminance and efficiency of OLEDs with a luminescent area of at least 0.049 cm² are not dependent on whether or not the ITO is located below the in situ PEDT layer. Comparison of Examples 3 and 4 also shows that a PEDT:PSS layer between the in situ layer and the PF-F8 layer (emitter layer) significantly improves the luminance and reduces the voltage.

It was also noticed during the tests in Examples 3 and 4 that the number of OLEDs per substrate without a short-circuit was significantly higher (approx. >80%) with a PEDT:PSS intermediate layer than without (approx, <20%). This proves that PEDT:PSS layers smooth the in situ layer.

Although the invention has been described in detail in the foregoing for the purpose of illustration, it is to be understood that such detail is solely for that purpose and that variations can be made therein by those skilled in the art without departing from the spirit and scope of the invention except as it may be limited by the claims.

1. A transparent electrode comprising:
(a) a first layer comprising at least one conductive polymer,
(b) a second layer, which is applied to said first layer, said second layer comprising at least one polymeric anion, and at least one member selected from the group consisting of polyaniline, substituted polyaniline and polythiophene having recurring units represented by general formula (I), 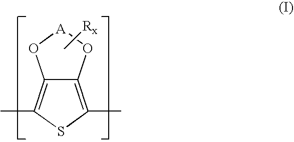
wherein,
A represents a radical selected from the group consisting of C₁ to C₅ alkylene radical and C₁ to C₅ alkylene radical substituted with a member selected from the group consisting of halogen, ether, thioether, disulphide, sulphoxide, sulphone, sulphonate, amino, aldehyde, keto, carboxylic acid ester, carboxylic acid, carbonate, carboxylate, cyano, alkylsilane, alkoxysilane, and carboxylamide,
R represents a radical selected from the group consisting of linear or branched C₁ to C₁₈ alkyl radical, C₅ to C₁₂ cycloalkyl radical, C₆ to C₁₄ aryl radical, C₇ to C₁₈ aralkyl radical, C₁ to C₄ hydroxyalkyl radical, and hydroxyl radical,
each of the C₁ to C₁₈ alkyl radical, C₅ to C₁₂ cycloalkyl radical, C₆ to C₁₄ aryl radical, C₇ to C₁₈ aralkyl radical and C₁ to C₄ hydroxyalkyl radical being optionally and independently substituted with a member selected from the group consisting of suphonate groups, carboxylate groups and combinations thereof, and
x represents an integer from 0 to 8,
provided that when x is greater than 1, each R may independently be the same or different.

2. The electrode of claim 1 wherein the conductive polymer of said first layer is selected from the group consisting of polythiophene, polypyrrole, polyaniline and combinations thereof.

3. The electrode of claim 1 wherein the conductive polymer of said first layer is a polythiophene with recurring units represented by general formula (I), wherein A, R and x have the meaning given in claim 1.

4. The electrode of claim 3 wherein for the polythiophene of the conductive polymer of the first layer, and for the polythiophene of the second layer, independently of one another,
A of formula (I) is selected from the group consisting of C₂-C₃ alkylene radical and C₂-C₃ alkylene radical substituted with a member selected from the group consisting of halogen, ether, thioether, disulphide, sulphoxide, sulphone, sulphonate, amino, aldehyde, keto, carboxylic acid ester, carboxylic acid, carbonate, carboxylate, cyano, alkylsilane, alkoxysilane, and carboxylamide, and
x of formula (I) represents 0 or 1.

5. The electrode of claim 4 wherein the polythiophene of the conductive polymer of the first layer, and the polythiophene of the second layer, independently of one another, is selected from poly(3,4-ethylenedioxythiophene).

6. The electrode of claim 1 wherein the polymeric anion of said second layer is selected from the group consisting of an anion of a polymeric carboxylic acid, an anion of a polymeric sulphonic acid and combinations thereof.

7. The electrode of claim 6 wherein the polymeric anion is an anion of polystyrene sulphonic acid.

8. The electrode of claim 1 wherein said first layer and said second layer each independently have a surface resistance of ≦1,000 Ω/sq.

9. The electrode of claim 1 wherein said electrode has a transmission value Y of at least 25, as determined in accordance with ASTM D1003-00 and ASTM E 308.

10. A process for producing a transparent electrode comprising,
(i) a first layer comprising at least one conductive polymer, and
(ii) a second layer, which is applied to said first layer, said second layer comprising at least one polymeric anion, and at least one member selected from the group consisting of polyaniline, substituted polyaniline and polythiophene having recurring units represented by general formula (I), 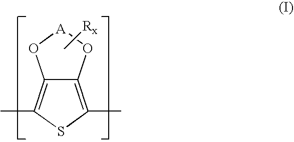
wherein,
A represents a radical selected from the group consisting of C₁ to C₅ alkylene radical and C₁ to C₅ alkylene radical substituted with a member selected from the group consisting of halogen, ether, thioether, disulphide, sulphoxide, sulphone, sulphonate, amino, aldehyde, keto, carboxylic acid ester, carboxylic acid, carbonate, carboxylate, cyano, alkylsilane, alkoxysilane, and carboxylamide,
R represents a radical selected from the group consisting of linear or branched C₁ to C₁₈ alkyl radical, C₅ to C₁₂ cycloalkyl radical, C₆ to C₁₄ aryl radical, C₇ to C₁₈ aralkyl radical, C₁ to C₄ hydroxyalkyl radical, and hydroxyl radical,
each of the C₁ to C₁₈ alkyl radical, C₅ to C₁₂ cycloalkyl radical, C₆ to C₁₄ aryl radical, C₇ to C₁₈ aralkyl radical and C₁ to C₄ hydroxyalkyl radical being optionally and independently substituted with a member selected from the group consisting of suphonate groups, carboxylate groups and combinations thereof, and
x represents an integer from 0 to 8,
provided that when x is greater than 1, each R may independently be the same or different,
said process comprising,
(a) providing a substrate,
(b) applying to said substrate precursors of the conductive polymer of said first layer, and polymerizing said precursors by a method selected from the group consisting of (i) chemical oxidation in the presence of at least one oxidizing agent, and (ii) electrochemical polymerization, thereby forming said conductive polymer,
(c) optionally washing and drying said first layer,
(d) applying to said first layer a dispersion comprising at least one polymeric anion, and at least one member selected from the group consisting of polyaniline, substituted polyaniline and polythiophene having recurring units represented by general formula (I), said dispersion optionally comprising an organic solvent, and
(e) solidifying said dispersion by a method selected from the group consisting of (i) removing said organic solvent from said dispersion, (ii) crosslinking said dispersion, and (iii) a combination of (i) and (ii), thereby forming said second layer.

11. The process of claim 10 further comprising applying an adhesive to said substrate prior to the application of said first layer, said adhesive being interposed between said substrate and said first layer.

12. The process of claim 10 wherein said precursors of said conductive polymer of said first layer are selected from the group consisting of thiophenes, pyrroles, anilines and combinations thereof.

13. The process of claim 12 wherein said precursors of said conductive polymer of said first layer are thiophenes represented by general formula (II), 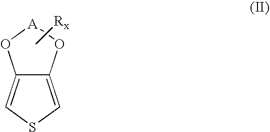
wherein A, R and x are as described in claim 10.

14. The process of claim 12 wherein said precursors of said conductive polymer of said first layer are thiophenes represented by general formula (IIa), 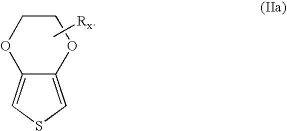
wherein R and x are as described in claim 10.

15. The process of claim 10 wherein said dispersion comprises a solvent selected from the group consisting of organic solvents, water and mixtures thereof.

16. The process of claim 10 wherein said precursors of the conductive polymer of said first layer are polymerized by chemical oxidation in the presence of at least one oxidizing agent.

17. An electro-optical structure comprising the transparent electrode of claim 1.

18. An article of manufacture selected from the group consisting of organic light-emitting diodes, organic solar cells, liquid crystal displays (LCDs) and optical sensors, wherein said article of manufacture comprises said transparent electrode of claim 1.

19. An electroluminescent arrangement comprising:
(a) at least two electrodes, at least one of said electrodes being the transparent electrode of claim 1; and
(b) an electro-optical active layer, said electro-optical active layer being interposed between two of said electrodes.

20. The electroluminescent arrangement of claim 19 wherein said electroluminescent arrangement has an anode side, and further comprises a plurality of highly conductive metal supply leads on said anode side.
